(19) United States
(12) Patent Application Publication
(10) Pub. No.: US 2018/0301528 A1
(43) Pub. Date: Oct. 18, 2018

(54) HIGH ELECTRON MOBILITY TRANSISTOR

(71) Applicant: Wavetek Microelectronics Corporation, Hsinchu County (TW)

(72) Inventor: Chih-Yen Chen, Tainan City (TW)

(21) Appl. No.: 15/605,900

(22) Filed: May 25, 2017

(30) Foreign Application Priority Data
Apr. 18, 2017 (TW) 106113002

(51) Int. Cl. H01L 29/06; H01L 29/20; H01L 29/205; H01L 29/207; H01L 29/778

(52) U.S. Cl. CPC H01L 29/0634; H01L 29/2003; H01L 29/7785; H01L 29/207; H01L 29/205

(57) ABSTRACT

A high electron mobility transistor includes a channel layer, a barrier layer, and a first anti-polarization layer. The barrier layer is disposed above the channel layer. The first anti-polarization layer is disposed under the channel layer. A thickness of the first anti-polarization layer is substantially equal to a thickness of the barrier layer. An atomic ratio of a group III element in the first anti-polarization layer is substantially equal to an atomic ratio of the group III element in the barrier layer.

### BACKGROUND OF THE INVENTION

### 1. Field of the Invention

The present invention relates to a high electron mobility transistor (HEMT), and more particularly, to an HEMT including an anti-polarization layer.

### 2. Description of the Prior Art

Because of the semiconductor characteristics, III-V semiconductor compounds may be applied in many kinds of integrated circuit devices, such as high power field effect transistors, high frequency transistors, or high electron mobility transistors (HEMTs). In the high electron mobility transistor, two semiconductor materials with different band-gaps are combined and heterojunction is formed at the junction between the semiconductor materials as a channel for carriers. In recent years, gallium nitride (GaN) based materials have been applied in the high power and high frequency products because of the properties of wider band-gap and high saturation velocity. Two-dimensional electron gas (2DEG) may be generated by the piezoelectricity property of the GaN-based materials, and the switching velocity may be enhanced because of the higher electron velocity and the higher electron density of the 2DEG.

In GaN HEMTs, the net polarization charge between the barrier layer and the channel layers is of positive polarity, which creates a potential well at the interface. The ionized carriers drifting into the potential well by the polarization field distribution form the 2DEG. Since the direction of polarization is polarity related, the position where the 2DEG can be formed is determined by the GaN polarity, namely, Ga polar or N polar. Therefore, a top barrier layer is used to sustain 2DEG in Ga-polar GaN HEMTs, while a back barrier layer is required in N-polar GaN HEMTs. In Ga-polar GaN HEMTs, the 2DEG is formed by the surface ionized carriers drifting into the potential well, and a positively polarized surface that can capture electrons during device operation may be formed. Problems such as current collapse may occur accordingly, and the operation performance and the reliability of the HEMT may be influenced.

### SUMMARY OF THE INVENTION

It is one of the objectives of the present invention to provide a high electron mobility transistor (HEMT). An anti-polarization layer is formed under a channel layer, and a thickness of the anti-polarization layer is substantially equal to a thickness of a barrier layer located above the channel layer. The purposes of reduced surface field (RESURF) and suppressing current collapse may be achieved by the anti-polarization layer, and the breakdown voltage of the HEMT may be enhanced accordingly.

A high electron mobility transistor is provided in an embodiment of the present invention. The high electron mobility transistor includes a channel layer, a barrier layer, and a first anti-polarization layer. The barrier layer is disposed above the channel layer. The first anti-polarization layer is disposed under the channel layer. A thickness of the first anti-polarization layer is substantially equal to a thickness of the barrier layer.

In the HEMT of the present invention, the thickness of the first anti-polarization layer disposed under the channel layer is comparable to the thickness of the barrier layer disposed over the channel layer, and the first anti-polarization layer may be used to change the potential distribution of the energy band diagram under (and including) the channel layer. Therefore, the channel layer may provide more ionized carriers to a potential well between the barrier layer and the channel layer, the polarized charge on the surface of the HEMT may be reduced accordingly, and the purposes of reducing surface field and suppressing current collapse may be achieved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing illustrating a high electron mobility transistor (HEMT) according to a first embodiment of the present invention.

FIG. 2 is a schematic drawing illustrating an HEMT according to a second embodiment of the present invention.

FIG. 3 is a schematic drawing illustrating an HEMT according to a third embodiment of the present invention.

FIG. 4 is a schematic drawing illustrating an HEMT according to a fourth embodiment of the present invention.

FIG. 5 is a schematic drawing illustrating an HEMT according to a fifth embodiment of the present invention.

FIG. 6 is a schematic drawing illustrating an HEMT according to a sixth embodiment of the present invention.

FIG. 7 is a schematic drawing illustrating an HEMT according to a seventh embodiment of the present invention.

FIG. 8 is a schematic drawing illustrating an HEMT according to an eighth embodiment of the present invention.

FIG. 9 is a schematic drawing illustrating an HEMT according to a ninth embodiment of the present invention.

FIG. 10 is a schematic drawing illustrating an HEMT according to a tenth embodiment of the present invention.

FIG. 11 is a schematic drawing illustrating an HEMT according to an eleventh embodiment of the present invention.

### DETAILED DESCRIPTION

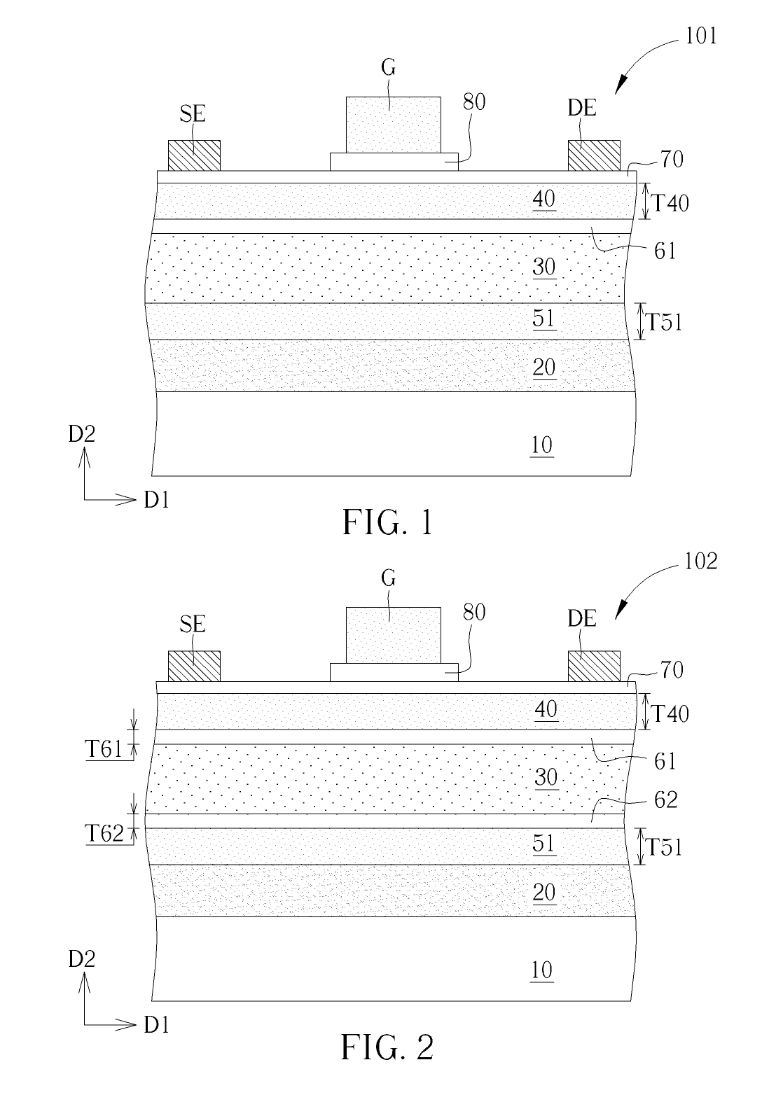

Please refer to FIG. 1. FIG. 1 is a schematic drawing illustrating a high electron mobility transistor (HEMT) according to a first embodiment of the present invention. As shown in FIG. 1, an HEMT 101 is provided in this embodiment. The HEMT 101 includes a channel layer 30, a barrier layer 40, and a first anti-polarization layer 51. The barrier 40 layer is disposed above the channel layer 30, and the first anti-polarization layer 51 is disposed under the channel layer 30. A thickness of the first anti-polarization layer 51 (such as a second thickness T51 shown in FIG. 1) is substantially equal to a thickness of the barrier layer 40 (such as a first thickness T40 shown in FIG. 1). In some embodiments, the channel layer 30 may include materials such as gallium nitride (GaN) and/or indium gallium nitride (InGaN), and the barrier layer 40 may include materials such as aluminum gallium nitride (AlGaN), aluminum indium nitride (AlInN), aluminum gallium indium nitride (AlGaInN) and/or aluminum nitride (AlN). Specifically, the HEMT 101 may be a Ga-polarity GaN HEMT, and the barrier layer 40 disposed above the channel layer 30 may be used to sustain a two-dimensional electron gas (2DEG) formed in the channel layer 30 and/or formed between the channel layer 30 and the barrier layer 40. The net polarization charge between the barrier layer 40 and the channel layer 30 is positive polarity, and that will create a potential well at the interface. The ionized carriers swept by the polarization field distribution into the potential well form the two-dimensional electron gas. Generally, the surface of the barrier layer 40 will become positively polarized when the ionized carriers gather at the potential well, the positively polarized surface may capture electrons during device operations and forma surface channel, and problems such as current collapse may occur and the operation performance of the HEMT 101 may be influenced accordingly. However, the first anti-polarization layer 51 having a thickness comparable to that of the barrier layer 40 is disposed under the channel layer 30 for altering the potential distribution of energy band diagram under (and including) the channel layer 30, and more ionized carriers maybe provided by the channel layer 30 to the potential well between the barrier layer 40 and the channel layer 30. The polarized charge on the surface of the HEMT 101 may be reduced accordingly, and the purposes of reduced surface field (RESURF) and suppressing the current collapse issue may be achieved. Additionally, the purposes of reducing surface field and suppressing the current collapse issue may be achieved by the first anti-polarization layer 51 without disposing an additional field plate, and problems generated by the field plate, such as the parasitic capacitance, may also be avoided apart from the enhancement of the breakdown voltage. The operation stability and the reliability of the HEMT may be improved accordingly.

Additionally, in some embodiments, the HEMT 101 may further include a gate electrode G, a source electrode SE, a drain electrode DE, and a buffer layer 20. The gate electrode G, the source electrode SE, and the drain electrode DE are disposed on the barrier layer 40. The source electrode SE and the drain electrode DE are disposed at two opposite sides of the gate electrode G in a first direction D1, but not limited thereto. The source electrode SE, the drain electrode DE, and the gate electrode G may include conductive metal materials or other suitable conductive materials respectively. The conductive metal materials mentioned above may include gold (Au), tungsten (W), cobalt (Co), nickel (Ni), titanium (Ti), molybdenum (Mo), copper (Cu), aluminum (Al), tantalum (Ta), palladium (Pd), platinum (Pt), a compound of the above-mentioned materials, a stack layer of the above-mentioned materials, or an alloy of the above-mentioned materials, but not limited thereto. The buffer layer may be disposed under the first anti-polarization layer 51, and the HEMT 101 may be disposed on a substrate 10, but not limited thereto. In some embodiments, the buffer layer 20 may include gallium nitride, aluminum gallium nitride, aluminum indium nitride, or other suitable buffer materials. The substrate 10 may include silicon substrate, silicon carbide substrate, gallium nitride substrate, sapphire substrate, or substrate formed by other appropriate materials.

For generating the required anti-polarization effect by the first anti-polarization layer 51, the thickness, the polarized charge, and/or the polarization field of the first anti-polarization layer 51 should be comparable to that of the barrier layer 40 for reducing the polarization at the surface of the barrier layer 40. In some embodiments, considering feasible process variation control, the thickness of the first anti-polarization layer 51 may be substantially equal to the thickness of the barrier layer 40 with a tolerance of ±25%. In other words, the second thickness T51 of the first anti-polarization layer 51 is equal to the first thickness T40 of the barrier layer 40 preferably, but the second thickness T51 of the first anti-polarization layer 51 may range from 0.75 times the first thickness T40 of the barrier layer 40 to 1.25 times the first thickness T40 of the barrier layer 40. The first anti-polarization layer 51 within this thickness range can still provide specific effect. In some embodiments, the tolerance described above may be further reduced to be ±10% or even ±5% for ensuring the uniformity of electrical properties between a plurality of the HEMTs 101, but not limited thereto. Additionally, in some embodiments, the material of the first anti-polarization layer 51 may be the same as the material of the barrier layer 40 preferably. In other words, the first anti-polarization layer 51 may include materials such as aluminum gallium nitride, aluminum indium nitride, aluminum gallium indium nitride, and/or aluminum nitride, but not limited thereto. In some embodiments, the first anti-polarization layer 51 and the barrier layer 40 may include a III-V compound respectively, and the III-V compound may include a first group III element and a second group III element. For example, in aluminum gallium nitride, the first group III element may be aluminum and the second group III element may be gallium, but not limited thereto. An atomic ratio of each of the group III elements in the first anti-polarization layer 51 is equal to that in the barrier layer 40. However, considering the feasible process variation control, an atomic ratio of the first group III element in the first anti-polarization layer 51 may be substantially equal to an atomic ratio of the first group III element in the barrier layer 40 with a tolerance of ±25%, and the first anti-polarization layer 51 within this atomic ratio range can still provide specific effect. For example, when the first anti-polarization layer 51 and the barrier layer 40 are both aluminum gallium nitride, the material composition of the barrier layer 40 may be shown as AlₓGa₁₋ₓN, the material composition of the first anti-polarization layer 51 may be shown as Al_{Y1}Ga_{1-Y1}N, and Y1 may range from 0.75× to 1.25×, but not limited thereto. Additionally, in some embodiments, the atomic ratio of the first group III element (such as aluminum) in the first anti-polarization layer 51 may be gradually decreased from the top of the first anti-polarization layer 51 to the bottom of the first anti-polarization layer 51. In other words, the portion of the first anti-polarization layer 51 connected to the buffer layer 20 may include less aluminum or include no aluminum for avoiding problems such as parasite 2DEG formed additionally and/or a bending issue of the substrate 10 during manufacturing processes because of the polarization difference and lattice-constant difference between the buffer layer 20 and the first anti-polarization layer 51, but not limited thereto. In some embodiments, the first anti-polarization layer 51 may also be doped with carbon or iron to increase the interface resistance for suppressing current leakage paths formed by the parasite 2DEG, but not limited thereto.

As shown in FIG. 1, in some embodiments, the HEMT 101 may further include a spacer layer 61, a cap layer 70, and a gate dielectric layer 80. The spacer layer 61 is disposed between the barrier layer 40 and the channel layer 30, and a material of the spacer layer 61 may be different from the material of the barrier layer 40 and the material of the channel layer 30. For example, the spacer layer 61 may include aluminum nitride, aluminum indium nitride, or other suitable III-V compounds. The cap layer 70 is disposed on the barrier layer 40, and the cap layer 70 may include gallium nitride, aluminum nitride, aluminum gallium nitride, or silicon nitride, but not limited thereto. The gate dielectric layer 80 may be at least partially disposed between the gate electrode G and the cap layer 70 in a vertical second direction D2. In some embodiments, the gate dielectric layer 80 may be a single layer structure or a structure of stacked multiple material layers. The material of the gate dielectric layer 80 may include aluminum nitride, silicon nitride (such as Si₃N₄), silicon oxide (such as SiO₂), aluminum oxide (such as Al₂O₃), hafnium oxide (such as HfO₂), lanthanum oxide (such as La₂O₃), lutetium oxide (such as Lu₂O₃), lanthanum lutetium oxide (such as LaLuO₃), or other appropriate dielectric materials.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

Please refer to FIG. 2. FIG. 2 is a schematic drawing illustrating an HEMT 102 according to a second embodiment of the present invention. As shown in FIG. 2, the difference between the HEMT 102 in this embodiment and the HEMT in the first embodiment mentioned above is that the HEMT 102 in this embodiment may further include a nitride layer 62 disposed between the channel layer 30 and the first anti-polarization layer 51, and a material of the nitride layer 62 is the same as the material of the spacer layer 61 preferably. Accordingly, the nitride layer 62 may be corresponding to the spacer layer 61, and the effects of suppressing surface polarization and reducing surface field may be further enhanced. In some embodiments, a thickness of the nitride layer 62 (such as a fourth thickness T62 shown in FIG. 2) may be substantially equal to a thickness of the spacer layer 61 (such as a third thickness T61 shown in FIG. 2) with a tolerance of ±25%. In other words, the fourth thickness T62 of the nitride layer 62 may be equal to the third thickness T61 of the spacer layer 61 preferably. However, considering feasible process variation control, the fourth thickness T62 of the nitride layer 62 may range from 0.75 times the third thickness T61 of the spacer layer 61 to 1.25 times the third thickness T61 of the spacer layer 61, and the nitride layer 62 within this thickness range can still provide specific effect. In some embodiments, the nitride layer 62 may also be doped with carbon or iron to increase the resistance at the interface between the nitride layer 62 and the first anti-polarization layer 51 for suppressing current leakage paths formed by parasite 2DEG, but not limited thereto.

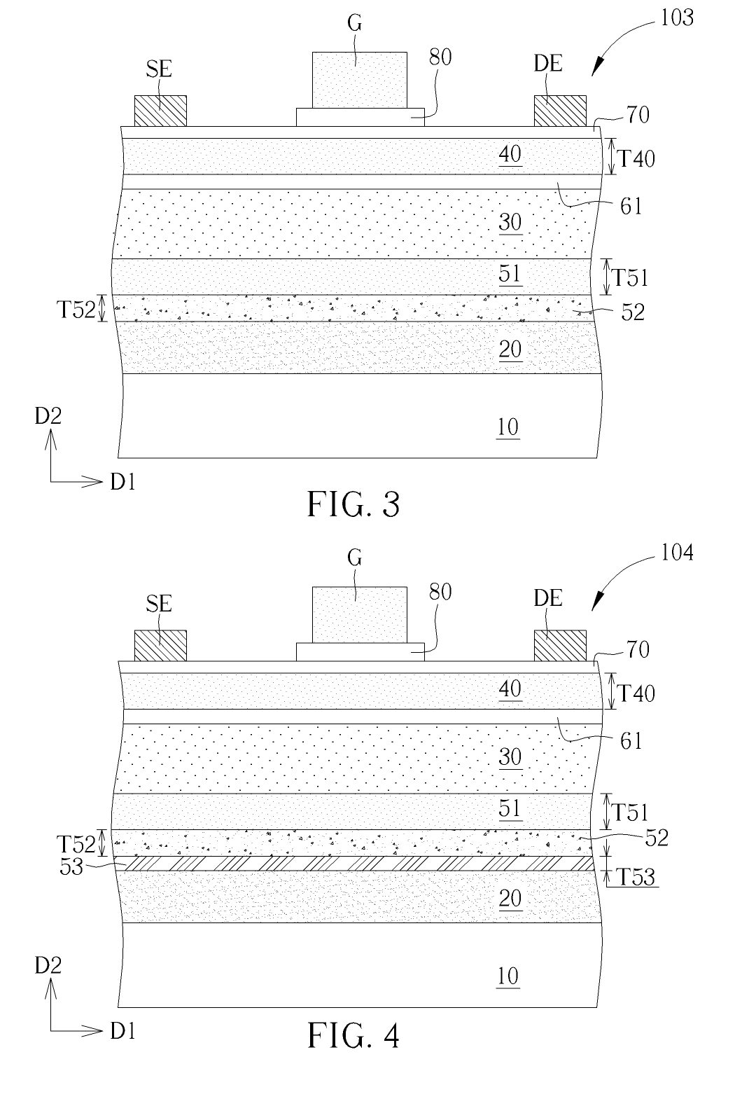

Please refer to FIG. 3. FIG. 3 is a schematic drawing illustrating an HEMT 103 according to a third embodiment of the present invention. As shown in FIG. 3, the difference between the HEMT 103 in this embodiment and the HEMT in the first embodiment mentioned above is that the HEMT 103 may further include a second anti-polarization layer 52 disposed under the first anti-polarization layer 51. The second anti-polarization layer 52 may include materials such as aluminum gallium nitride, aluminum indium nitride, aluminum gallium indium nitride, and/or aluminum nitride, but not limited thereto. The second anti-polarization layer 52 is disposed between the first anti-polarization layer 51 and the buffer layer 20 in the second direction D2, and the second anti-polarization layer 52 may be used to reduce the parasite 2DEG formed between the first anti-polarization layer 51 and the buffer layer 20. In some embodiments, a thickness of the second anti-polarization layer 52 (such as a fifth thickness T52 shown in FIG. 3) is less than the second thickness T51 of the first anti-polarization layer 51. For example, considering feasible process variation control, the fifth thickness T52 of the second anti-polarization layer 52 may be substantially equal to a half of the second thickness T51 of the first anti-polarization layer 51 with a tolerance of ±25%. In other words, the fifth thickness T52 of the second anti-polarization layer 52 may range from 0.375 times the second thickness T51 of the first anti-polarization layer 51 to 0.625 times the second thickness T51 of the first anti-polarization layer 51, but not limited thereto. Additionally, the first anti-polarization layer 51 and the second anti-polarization layer 52 may include a III-V compound respectively, and the III-V compound may include a first group III element and a second group III element. For example, the first anti-polarization layer 51 and the second anti-polarization layer 52 may be aluminum gallium nitride respectively, the first group III element in the aluminum gallium nitride may be aluminum, and the second group III element may be gallium, but not limited thereto. An atomic ratio of the first group III element in the second anti-polarization layer 52 may be less than an atomic ratio of the first group III element in the first anti-polarization layer 51. In some embodiments, the atomic ratio of the first group III element in the second anti-polarization layer 52 may be substantially equal to a half of the atomic ratio of the first group III element in the first anti-polarization layer 51 with a tolerance of ±25%. For example, when the first anti-polarization layer 51 and the second anti-polarization layer 52 are both aluminum gallium nitride, the material composition of the first anti-polarization layer 51 may be shown as Al_{Y1}Ga_{1-Y1}N, the material composition of the second anti-polarization layer 52 may be shown as Al_{Y2}Ga_{1-Y2}N, and Y2 may range from 0.375Y1 to 0.625Y1, but not limited thereto. Additionally, in some embodiments, for increasing the interface resistance in order to suppress the current leakage path generated by the parasite 2DEG formed between the first anti-polarization layer 51 and the second anti-polarization layer and/or the parasite 2DEG formed between the second anti-polarization layer 52 and the buffer layer 20, the second anti-polarization layer 52 may also be doped with carbon or iron, but not limited thereto.

Please refer to FIG. 4. FIG. 4 is a schematic drawing illustrating an HEMT 104 according to a fourth embodiment of the present invention. As shown in FIG. 4, the difference between the HEMT 104 in this embodiment and the HEMT in the third embodiment mentioned above is that the HEMT 104 in this embodiment may further include a third anti-polarization layer 53 disposed under the second anti-polarization layer 52. The third anti-polarization layer 53 may include materials such as aluminum gallium nitride, aluminum indium nitride, aluminum gallium indium nitride, and/or aluminum nitride, but not limited thereto. The third anti-polarization layer 53 is disposed between the second anti-polarization layer 52 and the buffer layer 20 in the second direction D2, and the third anti-polarization layer 53 may be used to reduce the parasite 2DEG formed between the second anti-polarization layer 52 and the buffer layer 20. In some embodiments, a thickness of the third anti-polarization layer 53 (such as a sixth thickness T53 shown in FIG. 4) is less than the fifth thickness T52 of the second anti-polarization layer 52. For example, considering feasible process variation control, the sixth thickness T53 of the third anti-polarization layer 53 may be substantially equal to a half of the fifth thickness T52 of the second anti-polarization layer 52 with a tolerance of ±25%. In other words, the sixth thickness T53 of the third anti-polarization layer 53 may range from 0.375 times the fifth thickness T52 of the second anti-polarization layer 52 to 0.625 times the fifth thickness T52 of the second anti-polarization layer 52, but not limited thereto. Additionally, the first anti-polarization layer 51, the second anti-polarization layer 52, and the third anti-polarization layer 53 may include a III-V compound respectively, and the III-V compound may include a first group III element and a second group III element. For example, the first group III element in aluminum gallium nitride may be aluminum, and the second group III element may be gallium, but not limited thereto. An atomic ratio of the first group III element in the third anti-polarization layer 53 may be less than an atomic ratio of the first group III element in the second anti-polarization layer 52. In some embodiments, the atomic ratio of the first group III element in the third anti-polarization layer 53 may be substantially equal to a half of the atomic ratio of the first group III element in the second anti-polarization layer 52 with a tolerance of ±25%. For example, when the first anti-polarization layer 51, the second anti-polarization layer 52, and the third anti-polarization layer 53 are all aluminum gallium nitride, the material composition of the second anti-polarization layer 52 may be shown as Al_{Y2}Ga_{1-Y2}N, the material composition of the third anti-polarization layer 53 may be shown as Al_{Y3}Ga_{1-Y3}N, and Y3 may range from 0.375Y2 to 0.625Y2, but not limited thereto. Additionally, in some embodiments, for increasing the interface resistance in order to suppress the current leakage path generated by the parasite 2DEG formed between the second anti-polarization layer 52 and the third anti-polarization layer 53 and/or the parasite 2DEG formed between the third anti-polarization layer 53 and the buffer layer 20, the third anti-polarization layer 53 may also be doped with carbon or iron, but not limited thereto.

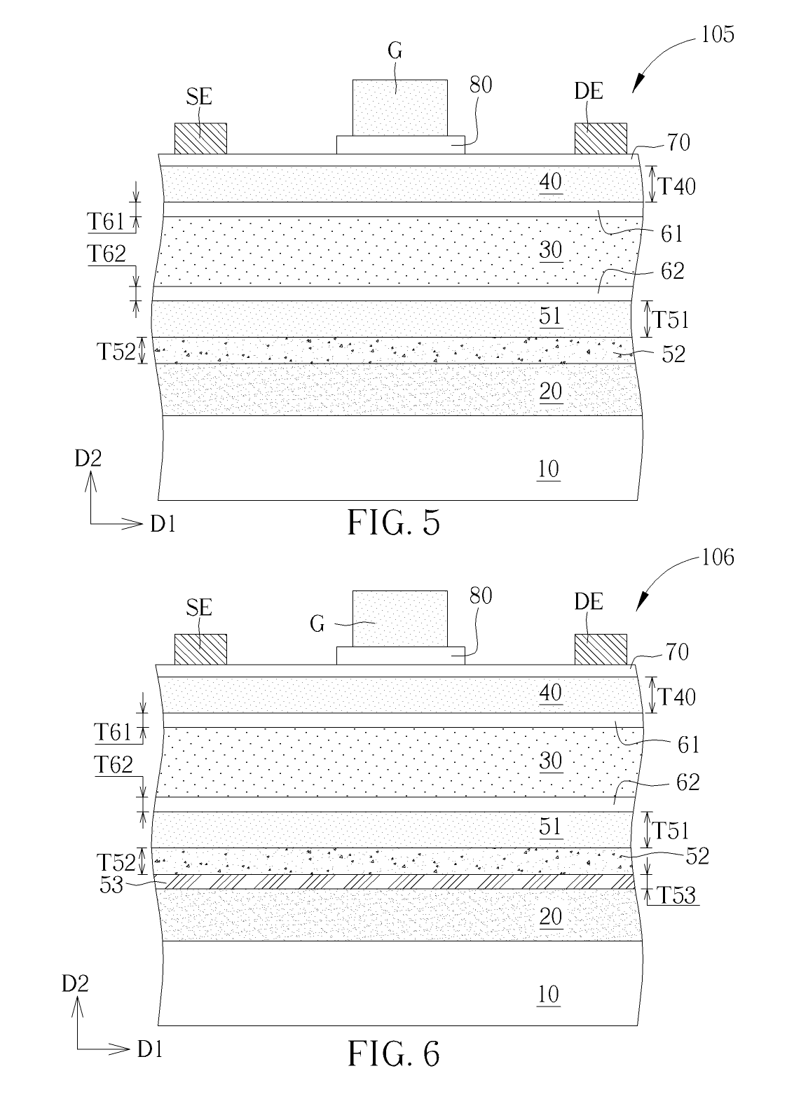

Please refer to FIG. 5. FIG. 5 is a schematic drawing illustrating an HEMT 105 according to a fifth embodiment of the present invention. As shown in FIG. 5, the difference between the HEMT 105 in this embodiment and the HEMT in the third embodiment mentioned above is that the HEMT 105 in this embodiment may further include the nitride layer 62 disposed between the channel layer 30 and the first anti-polarization layer 51, and the material of the nitride layer 62 is the same as the material of the spacer layer 61 preferably. Accordingly, the nitride layer 62 may be corresponding to the spacer layer 61, and the effects of suppressing surface polarization and reducing surface field may be further enhanced. The allocation and the material properties of the nitride layer 62 are detailed in the second embodiment mentioned above and will not be redundantly described.

Please refer to FIG. 6. FIG. 6 is a schematic drawing illustrating an HEMT 106 according to a sixth embodiment of the present invention. As shown in FIG. 6, the difference between the HEMT 106 in this embodiment and the HEMT in the fifth embodiment mentioned above is that the HEMT 106 in this embodiment may further include the third anti-polarization layer 53 disposed under the second anti-polarization layer 52, and the third anti-polarization layer 53 may be used to reduce the parasite 2DEG formed between the second anti-polarization layer 52 and the buffer layer 20. The allocation and the material properties of the third anti-polarization layer 53 are detailed in the fourth embodiment mentioned above and will not be redundantly described.

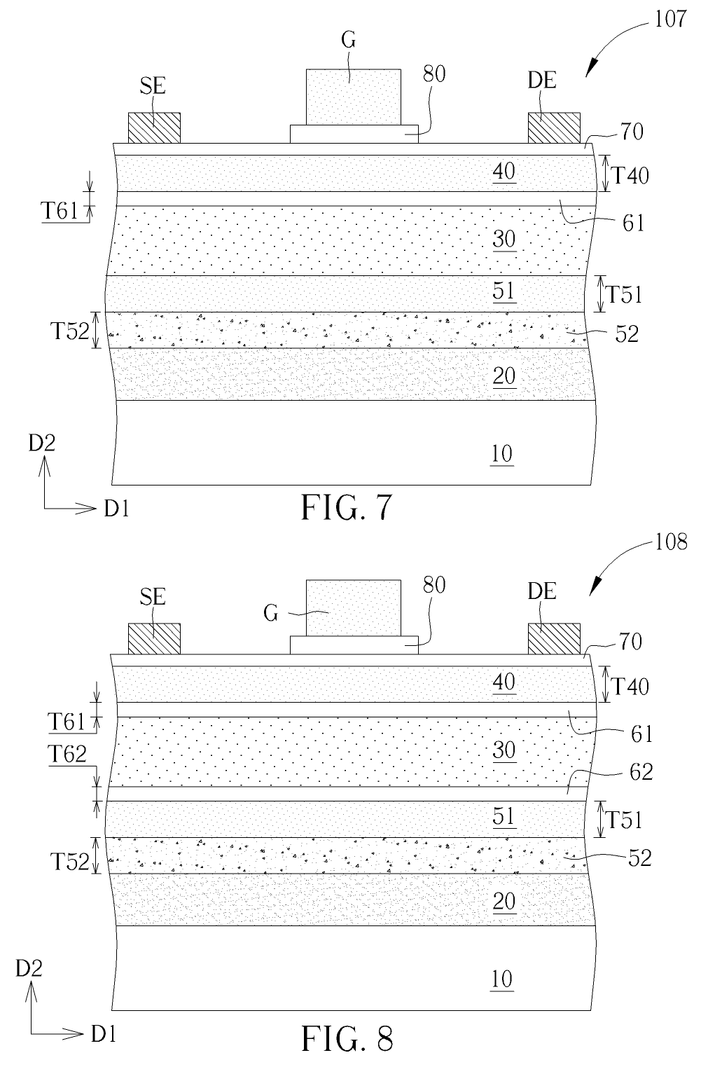

Please refer to FIG. 7. FIG. 7 is a schematic drawing illustrating an HEMT 107 according to a seventh embodiment of the present invention. As shown in FIG. 7, the difference between the HEMT 107 in this embodiment and the HEMT in the third embodiment mentioned above is that, in the HEMT 107 of this embodiment, the fifth thickness T52 of the second anti-polarization layer 52 may be substantially equal to the second thickness T51 of the first anti-polarization layer 51 with a tolerance of ±25%. In other words, the fifth thickness T52 of the second anti-polarization layer 52 is equal to the second thickness T51 of the first anti-polarization layer 51 preferably. However, considering the feasible process variation control, the fifth thickness T52 of the second anti-polarization layer 52 may range from 0.75 times the second thickness T51 of the first anti-polarization layer 51 to 1.25 times the second thickness T51 of the first anti-polarization layer 51. Additionally, when the second anti-polarization layer 52 is a III-V compound such as aluminum gallium nitride, the III-V compound includes a first group III element (such as aluminum) and a second group III element (such as gallium), and the atomic ratio of the first group III element in the second anti-polarization layer 52 may be gradually decreased from the top of the second anti-polarization layer 52 to the bottom of the second anti-polarization layer 52. In other words, the portion of the second anti-polarization layer 52 connected to the buffer layer 20 may include less aluminum or include no aluminum for avoiding problems such as parasite 2DEG formed additionally and/or a bending issue of the substrate 10 generated during manufacturing processes because of the polarization difference and lattice-constant difference between the buffer layer 20 and the second anti-polarization layer 52, but not limited thereto.

Please refer to FIG. 8. FIG. 8 is a schematic drawing illustrating an HEMT 108 according to an eighth embodiment of the present invention. As shown in FIG. 8, the difference between the HEMT 108 in this embodiment and the HEMT in the seventh embodiment mentioned above is that the HEMT 108 in this embodiment may further include the nitride layer 62 disposed between the channel layer 30 and the first anti-polarization layer 51, and the material of the nitride layer 62 is the same as the material of the spacer layer 61 preferably. Accordingly, the nitride layer 62 may be corresponding to the spacer layer 61, and the effects of suppressing surface polarization and reducing surface field may be further enhanced. The allocation and the material properties of the nitride layer 62 are detailed in the second embodiment mentioned above and will not be redundantly described.

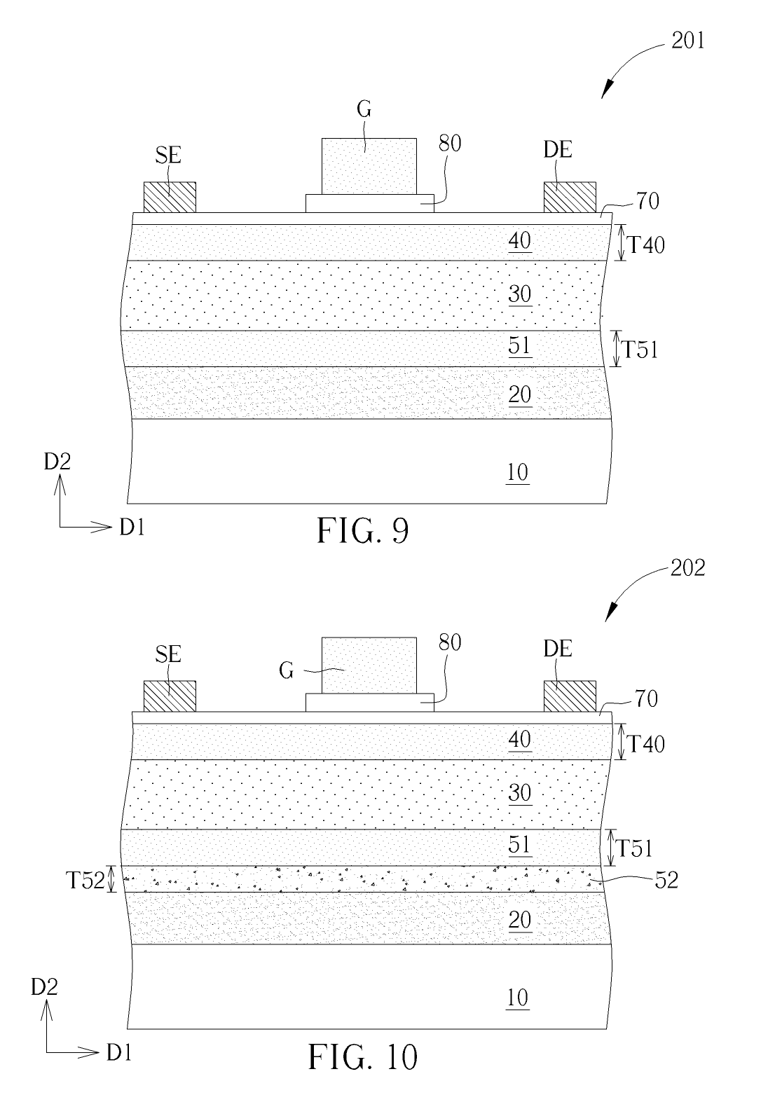

Please refer to FIG. 9. FIG. 9 is a schematic drawing illustrating an HEMT 201 according to a ninth embodiment of the present invention. As shown in FIG. 9, the difference between the HEMT 201 in this embodiment and the HEMT in the first embodiment mentioned above is that, in the HEMT 201 of this embodiment, the channel layer 30 and the barrier layer 40 may be binary compounds, such as gallium nitride and aluminum nitride respectively, but not limited thereto. In this condition, the barrier layer 40 may directly contact the channel layer 30, and the spacer layer described in the embodiments mentioned above will not be required to be disposed between the barrier layer 40 and the channel layer 30. Similarly, the material of the first anti-polarization layer 51 in this embodiment may be the same as the material of the barrier layer 40, such as aluminum nitride, but not limited thereto.

Please refer to FIG. 10. FIG. 10 is a schematic drawing illustrating an HEMT 202 according to a tenth embodiment of the present invention. As shown in FIG. 10, the difference between the HEMT 202 in this embodiment and the HEMT in the ninth embodiment mentioned above is that the HEMT 202 in this embodiment may further include the second anti-polarization layer 52 disposed under the first anti-polarization layer 51. The second anti-polarization layer 52 is disposed between the first anti-polarization layer 51 and the buffer layer 20 in the second direction D2, and the second anti-polarization layer 52 may be used to reduce the parasite 2DEG formed between the first anti-polarization layer 51 and the buffer layer 20. The allocation and the material properties of the second anti-polarization layer 52 are detailed in the third embodiment mentioned above and will not be redundantly described. It is worth noting that because the second anti-polarization layer 52 may not be corresponding to the condition of the barrier layer 40, the material of the second anti-polarization layer 52 in this embodiment may be different from the material of the first anti-polarization layer 51. For example, the second anti-polarization layer 52 may be aluminum gallium nitride and the first anti-polarization layer 51 may be aluminum nitride, but not limited thereto.

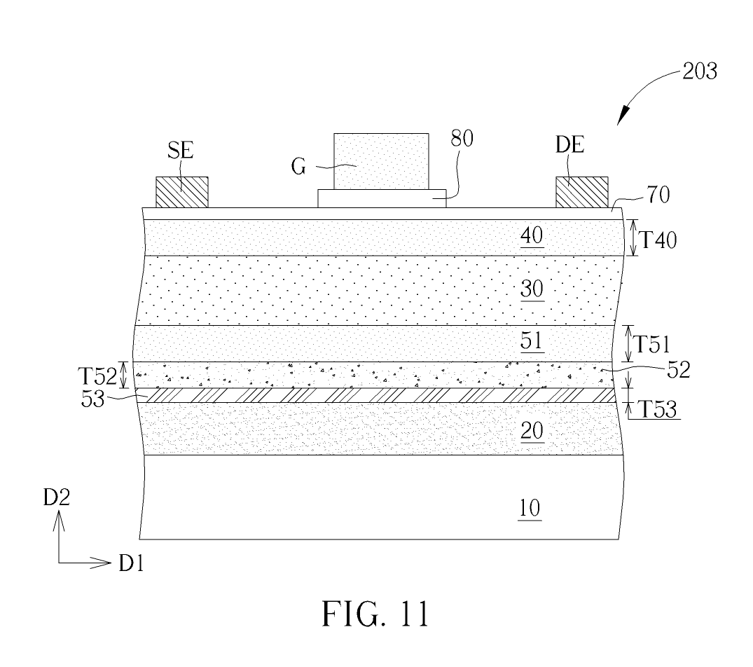

Please refer to FIG. 11. FIG. 11 is a schematic drawing illustrating an HEMT 203 according to an eleventh embodiment of the present invention. As shown in FIG. 11, the difference between the HEMT 203 in this embodiment and the HEMT in the tenth embodiment mentioned above is that the HEMT 203 in this embodiment may further include the third anti-polarization layer 53 disposed under the second anti-polarization layer 52, and the third anti-polarization layer 53 may be used to reduce the parasite 2DEG formed between the second anti-polarization layer 52 and the buffer layer 20. In this embodiment, the sixth thickness T53 of the third anti-polarization layer 53 may be substantially equal to the fifth thickness T52 of the second anti-polarization layer 52. The sixth thickness T53 of the third anti-polarization layer 53 and the fifth thickness T52 of the second anti-polarization layer 52 maybe both less than the second thickness T51 of the first anti-polarization layer 51. For example, considering the feasible process variation control, the sixth thickness T53 of the third anti-polarization layer 53 may be substantially equal to the fifth thickness T52 of the second anti-polarization layer 52 with a tolerance of ±25%, and the sixth thickness T53 and the fifth thickness T52 may be substantially equal to a half of the second thickness T51 of the first anti-polarization layer 51 with a tolerance of ±25% respectively. In other words, the sixth thickness T53 of the third anti-polarization layer 53 may range from 0.75 times the fifth thickness T52 of the second anti-polarization layer 52 to 1.25 times the fifth thickness T52, and the sixth thickness T53 and the fifth thickness T52 may range from 0.375 times the second thickness T51 to 0.625 times the second thickness T51 respectively, but not limited thereto. Additionally, the second anti-polarization layer 52 and the third anti-polarization layer 53 may include a III-V compound respectively, such as aluminum gallium nitride. When the second anti-polarization layer 52 and the third anti-polarization layer 53 are both aluminum gallium nitride, the material composition of the second anti-polarization layer 52 may be shown as Al_{Y2}Ga_{1-Y2}N, and the material composition of the third anti-polarization layer 53 may be shown as Al_{Y3}Ga_{1-Y3}N, wherein Y2 may be about 0.25±25%, and Y3 may be about 0.125±25%. In other words, Y2 may range from 0.1875 to 0.3125, and Y3 may range from 0.09375 to 0.15625, but not limited thereto.

It is worth noting that the tolerance described in the embodiments mentioned above may be reduced to be ±10% or even ±5% for ensuring the uniformity of the electrical properties between the high electron mobility transistors, but not limited thereto.

To summarize the above descriptions, in the HEMT of the present invention, the anti-polarization layer may be used to alter the potential distribution of energy band diagram under (and including) the channel layer, and more ionized carriers may be provided by the channel layer to the potential well between the barrier layer and the channel layer. The polarized charge on the surface of the HEMT may be reduced, and the purposes of reduced surface field (RESURF) and suppressing the current collapse issue may be achieved without disposing an additional field plate. Therefore, the breakdown voltage of the HEMT of the present invention may be enhanced and the problems generated by the field plate, such as the parasitic capacitance, may be avoided. The operation stability and the reliability of the HEMT may be improved accordingly.

Those skilled in the art will readily observe that numerous modifications and alterations of the device and method may be made while retaining the teachings of the invention. Accordingly, the above disclosure should be construed as limited only by the metes and bounds of the appended claims.

1. A high electron mobility transistor (HEMT), comprising:
a channel layer;
a barrier layer disposed above the channel layer;
a first anti-polarization layer disposed under the channel layer, wherein a thickness of the first anti-polarization layer is substantially equal to a thickness of the barrier layer with a tolerance of ±25%;
a spacer layer disposed between the barrier layer and the channel layer, wherein the material of the spacer layer is different from the material of the barrier layer and the material of the channel layer; and
a nitride layer disposed between the channel layer and the first anti-polarization layer, wherein a material of the nitride layer is the same as the material of the spacer layer.

2. (canceled)

3. The HEMT of claim 1, wherein the material of the first anti-polarization layer is the same as the material of the barrier layer.

4. The HEMT of claim 3, wherein the first anti-polarization layer and the barrier layer comprise a III-V compound respectively, and the III-V compound comprises a first group III element and a second group III element.

5. The HEMT of claim 4, wherein the atomic ratio of the first group III element in the first anti-polarization layer is substantially equal to the atomic ratio of the first group III element in the barrier layer with a tolerance of ±25%.

6. The HEMT of claim 4, wherein the atomic ratio of the first group III element in the first anti-polarization layer is gradually decreased from the top of the first anti-polarization layer to the bottom of the first anti-polarization layer.

7. The HEMT of claim 1, wherein the first anti-polarization layer is doped with carbon or iron.

8. (canceled)

9. The HEMT of claim 1, wherein the thickness of the nitride layer is substantially equal to the thickness of the spacer layer with a tolerance of ±25%.

10. The HEMT of claim 1, further comprising:
a second anti-polarization layer disposed under the first anti-polarization layer.

11. The HEMT of claim 10, wherein the thickness of the second anti-polarization layer is less than the thickness of the first anti-polarization layer.

12. The HEMT of claim 11, wherein the thickness of the second anti-polarization layer is substantially equal to a half of the thickness of the first anti-polarization layer with a tolerance of ±25%.

13. The HEMT of claim 10, wherein the thickness of the second anti-polarization layer is substantially equal to the thickness of the first anti-polarization layer with a tolerance of ±25%.

14. The HEMT of claim 10, wherein the first anti-polarization layer and the second anti-polarization layer comprise a III-V compound respectively, and the III-V compound comprises a first group III element and a second group III element.

15. The HEMT of claim 14, wherein the atomic ratio of the first group III element in the second anti-polarization layer is less than the atomic ratio of the first group III element in the first anti-polarization layer.

16. The HEMT of claim 15, wherein the atomic ratio of the first group III element in the second anti-polarization layer is substantially equal to a half of the atomic ratio of the first group III element in the first anti-polarization layer with a tolerance of ±25%.

17. The HEMT of claim 14, wherein the atomic ratio of the first group III element in the second anti-polarization layer is gradually decreased from the top of the second anti-polarization layer to the bottom of the second anti-polarization layer.

18. The HEMT of claim 10, wherein the second anti-polarization layer is doped with carbon or iron.

19. The HEMT of claim 10, further comprising:
a third anti-polarization layer disposed under the second anti-polarization layer, wherein the thickness of the third anti-polarization layer is less than the thickness of the second anti-polarization layer.

20. The HEMT of claim 19, wherein the thickness of the third anti-polarization layer is substantially equal to a half of the thickness of the second anti-polarization layer with a tolerance of ±25%.

21. The HEMT of claim 19, wherein the second anti-polarization layer and the third anti-polarization layer comprise a III-V compound respectively, the III-V compound comprises a first group III element and a second group III element, and the atomic ratio of the first group III element in the third anti-polarization layer is less than the atomic ratio of the first group III element in the second anti-polarization layer.

22. The HEMT of claim 21, wherein the atomic ratio of the first group III element in the third anti-polarization layer is substantially equal to a half of the atomic ratio of the first group III element in the second anti-polarization layer with a tolerance of ±25%.

23. The HEMT of claim 19, wherein the third anti-polarization layer is doped with carbon or iron.

24. The HEMT of claim 1, wherein the barrier layer and the first anti-polarization layer are an aluminum gallium indium nitride (AlGaInN) layer respectively, and the channel layer is a gallium nitride (GaN) layer.
